(19) United States
(12) Patent Application Publication
(10) Pub. No.: US 2005/0052856 A1
(43) Pub. Date: Mar. 10, 2005

(54) Method and apparatus having field replaceable units with electrical connectors

(75) Inventor: Emrys J. Williams, Milton Keynes (GB)

Correspondence Address: MEYERTONS, HOOD, KIVLIN, KOWERT & GOETZEL, P.C., P.O. BOX 398, AUSTIN, TX, 78767-0398, US

(73) Assignee: Sun Microsystems, Inc., Santa Clara, CA (US)

(21) Appl. No.: 10/654,728

(22) Filed: Sep. 4, 2003

(51) Int. Cl. H05K 7/14; H05K 7/18

(52) U.S. Cl. 361/796

(57) ABSTRACT

Apparatus is provided having a chassis with a plurality of slots. Multiple electrical field replaceable units (FRUs) or modules are inserted into respective slots. Each inserted module has at least one module electrical connector in engagement with a mating chassis electrical connector. In addition, each inserted module has a module restraint in engagement with a mating chassis restraint. In combination, these restraints act to retain the module in the slot. The apparatus further includes a management system that configures and deconfigures modules inserted into the slots. The management system sets a control signal for each module, which is fed to the relevant module, indicative of whether the module may be removed from its respective slot. This control signal is passed through the module, and made externally accessible when the module is inserted into its respective slot.

### FIELD OF THE INVENTION

The present invention relates to electronic systems such as computers that contain field replaceable units (FRUs) or modules inserted into a rack structure.

### BACKGROUND OF THE INVENTION

Modern computer systems are often based on a modular system, in which a given system is built up from modules inserted into a rack framework. This provides great flexibility in terms of overall system configuration. For example, a system may have two or more of a given hardware module (processing unit, storage subsystem, etc.) in order to increase the overall capacity of the installation. Furthermore, having multiple copies of a particular module permits redundancy or fault tolerance against failure of one of the modules.

The ongoing maintenance of such systems typically includes upgrading or replacing various hardware and software components. Hardware maintenance may be performed in order to enhance or modify the capabilities of the system, typically by adding new modules. These new modules may be in addition to or as a replacement for (perhaps upgrades of) existing modules. There is also a need to remove failed modules; if desired, properly operational units may then be inserted in the place of the failed modules.

Hardware maintenance of an installed computer system is generally performed by visiting service engineers or technicians. Many systems are specifically designed to include various field-replaceable units (FRUs), which can be replaced on-site if necessary by the visiting engineer. A common service task is therefore to identify a failed FRU in a system, and to replace it with a working FRU.

An important concern for modern computer systems is high availability, frequently 24×7 for commercial web servers. Accordingly, many FRUs are designed to be hot-pluggable; in other words, they can be inserted into the system, without having first to power down the complete system. Instead, the system automatically detects the newly inserted module, and performs the necessary (re)configuration procedures.

A standard physical arrangement for a rack-mounted system is to provide multiple parallel slots (either vertical or horizontal), with each slot accommodating a module, which is typically based around a printed circuit board (PCB). Modules are inserted into their corresponding slots from the front of the rack, and then slid into full engagement with the system by pushing the module towards the back of the rack. In order to provide power and other electrical signals (e.g. data lines) to the module, the leading edge of the module (on insertion) is usually provided with one or more electrical connectors, each normally comprising multiple pins. These connectors then mate with corresponding connectors located in the rack at the back of the slot.

As the complexity of systems increases, the number of pins used for connections between the module and the rack tends to get larger and larger. This then implies that a greater force is needed to push the module into the rack, in order to ensure proper engagement of the electrical connectors. Unfortunately, at the same time as the pins are becoming more numerous, they are also generally becoming smaller as well, and hence more delicate. This means that if the insertion force on the module is misdirected at all, so that the mating connectors are not properly aligned with one another, then there is the risk of damaging the connector pins as the male and female connector portions are pressed together. This can lead to the newly inserted device malfunctioning, thereby undermining the whole point of the service operation (and representing a potent source of customer frustration).

Various steps have been taken to try to ameliorate the above situation. One common technique is the provision of one or more guide rails to constrain the positioning of a module as it is inserted into its slot. However, the decreasing size of pins has also led to pins being more closely packed within a connector. This reduces the margin of error available for positioning the module within the slot, and hence the manufacturing tolerances for the size and location of the guide rails. Note also that as the guide rails constrain the position of the module ever more tightly, this will typically lead to increased frictional resistance to motion of the module within the slot. Consequently, the insertion force required to push the module to the back of the slot may rise significantly, which is undesirable given the delicacy of the connector pins.

It is possible to mechanically regulate the insertion force, such as by providing one or more injection levers on the front of the rack. These then interact with a module that is nearly completely inserted to provide a controlled force for pushing the module the extra distance required to engage the connectors at the back of the slot. In other words, the final part of the insertion process is performed by the technician operating the injection lever, rather than by pushing on the module itself. This then helps to ensure that the connectors are not inadvertently damaged by the application of excessive force.

The injection levers are of necessity placed at the front of the rack or slot, so as to allow a technician to access them. In contrast, the mating of the connectors occurs at the rear of the slot (in a largely inaccessible location, hence the alignment problem). Consequently, there is a significant distance comprising the full length of the slot between the position of the injection lever(s) and that of the connectors. This then places stringent mechanical constraints on the placement and operation of the injection lever(s), in order to avoid any mismatch during connector mating. Thus a very slight angular displacement in the orientation of the module at the front of the slot will produce a relatively large lateral displacement in the position of the connector on the module at the rear of the slot.

Another known mechanism to support the accurate insertion of a module into a rack slot is to provide one or more screw engagements at the back of the slot. Typically for example, a module carries a screw, which is free to rotate with respect to the module (and also usually has a certain play in the direction of insertion). The screw is received by a corresponding thread at the rear of the slot. Normally, the screw starts to enter this thread prior to the connectors making engagement. Then, as the screw progresses further into the thread, it begins to pull the connectors on the module and the rack into engagement with one another.

Note that because the screw is provided at the leading edge of the module, closely adjacent to the pins themselves, it is relatively easy to ensure correct positioning of the screw relative to the pins. Therefore, as the screw tightens in the thread, it automatically draws the male and female connectors into correct alignment with one another. In addition, the screw action provides a reliable and controlled final insertion force to overcome the resistance of the male and female connectors to engage one another.

It will be appreciated that although the module screws engage the rack at the rear of the slot, they must be accessible to the technician who has to tighten them (or to loosen them for module release). One possibility is to provide a hollow shaft for each screw along the length of the module. This then allows a technician to access and operate the screws at the rear of the slot by inserting a long screwdriver down this shaft. An alternative possibility is to increase the length of the screw, so that it has a long neck that extends right down the shaft to the front of the slot, where a technician can access the screw head directly.

Modern computer systems may have a very large number of modules in multiple racks. This can sometimes make things confusing for an engineer to determine exactly which module to replace. Thus even if it is known that a particular module (with a certain logical address) is to be replaced, identifying the physical location of the module that corresponds to this may be difficult. This can lead to the situation where the technician attempts to remove an incorrect module, one that is still functioning properly and should, in fact, remain in the system.

There can be several adverse consequences of inadvertently removing a module in operational mid-stream. Thus there may be loss of data within or in transit through the module concerned. There is also a possibility of causing the entire system to crash, dependent on the nature of the processing being performed by the module in question. Furthermore, the sudden disconnection of live pins may cause transients, disrupting communications on lines attached to the pins (both within the module and within the computer system itself), and potentially even causing hardware damage to sensitive components.

Note that even if the correct module is identified by the technician, there is still a risk that he or she will try to remove it from the system before the correct de-configuration has occurred. Thus the module in question may still be working and involved in system operations (for example, if the module in question is to be replaced by an upgraded module). Prior to removing the module therefore, the system needs to deconfigure the appropriate module, in order to terminate operations within the module. Unfortunately, in some situations a technician may forget to initiate such deconfiguration, leading to the problems discussed above of removing a live module from the system.

### SUMMARY OF THE INVENTION

Accordingly, one embodiment of the invention provides apparatus comprising a chassis having a plurality of slots. Electrical modules may be inserted into respective slots in the chassis. Each such module has opposed front and back portions, where the back portion is inserted first into the respective slot for the module. The back portion of a module has at least one module electrical connector that engages a mating chassis electrical connector. The back portion of a module further has at least one module restraint that engages a mating chassis restraint, thereby helping to retain the module in its slot. Note that the mechanical restraint to retain the module in the slot may be separate from the electrical connector, or the two may be provided integrated together in a combined unit.

The apparatus further includes a management system that configures and deconfigures modules inserted in the slots. The management system also generates a control signal for each inserted module that is indicative of whether the module may be removed from its respective slot (for example, whether the module has yet been deconfigured). The control signal may also be used to provide other information relevant to the service operation to be performed, such as indicating a maximum torque to be used in removing a module from its slot. The control signal is received by the relevant module from the management system, and then made externally accessible via an interface on the front portion of the module.

In a typical usage situation, a service engineer has a portable powered module ejector device, such as an electric screwdriver, to remove the module from the slot. The module ejector device is arranged to receive the control signal, and to disable removal of the module if the system is not yet ready (e.g. the module has not yet been deconfigured). Consequently, the premature or inadvertent removal of a module from its slot can be prevented, thereby maintaining the proper integrity of the system.

The module restraint generally extends from the back portion of the module, where it engages the chassis restraint, to the front portion of the module, where it is externally accessible for manipulation by the handheld module ejector. In one particular embodiment, the module restraint comprises a bolt with a screw thread, with the chassis restraint comprising a hole with a corresponding screw thread for receiving and engaging the bolt. The use of a bolt or screw for the mechanical restraint has the benefit that as the bolt is rotated and so is drawn further into the chassis, a controlled force applied on the electrical connector(s) to engage one another. At the same time, as the bolt engages the screw hole, this tends to hold the module steady and in the correct position relative to the chassis.

In order to protect the bolt from damage when the module is out of the chassis, the bolt may be recessed into the module. The chassis restraint (i.e. the hole) is then typically formed in a raised portion of the chassis, which corresponds to (and engages) the recessed portion of the module containing the bolt. Alternatively, the module restraint may comprise a female connector member that receives the chassis restraint as the male connector member. This latter approach again avoids the module restraint protruding outside the module where it would be at risk of damage. (Although the chassis male connector does protrude into the slot itself, this is a relatively safe environment).

In some implementations, the module restraint comprises a pair of parallel bolts, each having a screw thread, with the chassis restraint then having a corresponding pair of holes for receiving and engaging respective bolts. The use of two (or more) bolts in this manner prevents any rotational offset of the module relative to the chassis (about the direction of insertion). Note that in this configuration, the module generally includes a drive mechanism to rotate the pair of bolts in synchronism with one another. This then ensures that proper alignment is maintained while the module is inserted into or removed from a slot.

The control signal to indicate whether or not the module can be removed from a slot is conveniently provided from the management system to the module via the chassis electrical connector and the module electrical connector, although some wireless mechanism could be used instead. The control signal is then passed from the back of the module to the front, where it is accessible by the powered module ejector. In one embodiment, a socket is provided on the front of the module, which receives a plug from the powered module ejector. The socket can be used to pass power and the control signal from the module to the powered module ejector. Alternatively, the module ejector may not require power from the module itself, but rather may have its own source (e.g. a battery pack).

Instead of using a wired connection to provide the control signal from the module to the powered module ejector, this may be achieved instead using a wireless connection, such as a microwave or infrared data link. A further possibility is to use a lamp to provide an optical control signal. In one particular embodiment, the control signal is used to illuminate a lamp on the chassis at the rear of a slot. A module then incorporates a light guide that channels light from the lamp to the front of the module. This allows the presence (or absence) of the control signal to be determined by the powered module ejector by detecting whether any light is emanating from the light guide, typically by using a photodiode or other such light-sensitive device.

Irrespective of the exact configuration, by default the powered module ejector will not normally operate (electrically) without receiving a positive control signal from the module indicating that the system is ready for the module to be removed. This then ensures that the powered module ejector will be suitably disabled if the engineer forgets to make the appropriate connection to the module. For example, the module ejector may have a specific lead to be plugged into the module for receiving the control signal (with a separate lead for the power cable, or perhaps no power lead at all, if the ejector is battery-powered). The powered module ejector may then require this control signal lead to be plugged into the module and a positive control signal received over the lead, in order to be operated to remove the module.

The control signal link between the module and the powered module ejector (whether wired or wireless) may be arranged to prevent the powered module ejector from receiving a control signal from one module, but then being used to remove a different module (perhaps in an adjacent slot to the first module). For example, in one embodiment, the powered module ejector receives the control signal from the module over a lead of restricted length. This ensures that the powered module ejector is only able to engage (and remove) the particular module from which the control signal is being received. Alternatively, if a wireless link is being used to transmit the control signal, the link may be arranged to have limited range or directionality, so that the control signal can only be received by a powered module ejector that is engaging that specific module.

In one embodiment, the management system is responsive to an alert signal received from or via the module to deconfigure the module prior to generating the control signal. This ensures that a module is not removed before it has been properly deconfigured. The alert signal may be generated by engaging the powered module ejector with the module to be removed, such as by plugging a lead from the powered module ejector into the module (this same lead can then be used for receiving the control signal that enables the module to be removed). Another possibility is that the alert signal is sent in response to the module detecting the presence of a powered module ejector, such as by establishing an IR link that could later be used for passing the control signal back to the module ejector.

In systems where modules can be hot plugged into a bus (or hot removed from a bus), where the bus is shared between multiple modules, the action of inserting or removing a module may generate electrical noise on the bus. This noise may in turn impact the operations of the other modules. One mechanism to avoid such problems is for the management system to suspend communications on the bus during insertion and/or removal of a module with respect to the bus. Communications can then be resumed after the insertion or removal has completed, with only marginal impact on the overall processing throughput of the system. Such suspension might be triggered by receipt of an alert signal, as discussed above. Alternatively, the suspension might be timed to coincide with the provision by the management system (for a limited period) of a control signal to allow removal of a module from the bus.

Another embodiment of the invention provides a method for removing an electrical module from apparatus comprising a chassis having a plurality of slots, with electrical modules inserted into respective slots. The method comprises determining that a module needs removal from the apparatus, and deconfiguring the relevant module by a management system. The management system then sets a control signal to indicate that the module is now ready for removal. This control signal is made available for external access from the module, such as by a portable module ejector device. This device is only operable to remove a module from the chassis if the control signal from the module indicates that the module is allowed to be so removed (e.g. it has been properly deconfigured, etc).

Another embodiment of the invention provides an electrical module for insertion into a rack-mounted system having a plurality of slots. The module has opposed front and back portions, such that the back portion is inserted first into a slot for the module. The module comprises at least one module electrical connector on the back portion of the module for engagement with a mating chassis electrical connector. The module further comprises at least one module restraint on the back portion of the module for engagement with a mating chassis restraint to retain the module in the slot. A communications link extends from the back portion of the module to the front portion. This link is operable to receive a control signal from the chassis (when the module is located in a slot), and to forward the control signal to an externally accessible interface on the front portion of the module. The control signal is indicative of whether the module can be removed from the slot.

Another embodiment of the invention provides a powered module ejector for use with apparatus comprising a chassis having a plurality of slots, into which a plurality of electrical modules may be respectively inserted. Each module has opposed back and front portions, such that the back portion is inserted first into the relevant slot for the module. On the back portion of a module is at least one module electrical connector in engagement with a mating chassis electrical connector, and at least one module restraint in engagement with a mating chassis restraint to retain the module in the slot. In used, the powered module ejector receives a control signal from a module, which is indicative of whether the module may be removed from its respective slot. The powered module ejector is configured to operate (electrically) only in response to the control signal indicating that the module may be removed from its respective slot. One possibility is to produce such a powered module ejector by adding an appropriate adapter to a conventional electric screwdriver.

### BRIEF DESCRIPTION OF THE DRAWINGS

Various embodiments of the invention will now be described in detail by way of example only with reference to the following drawings in which like reference numerals pertain to like elements and in which:

FIGS. 1 and 2 are simplified schematic perspective and plan views respectively of a rack-mounted modular computer system;

FIG. 3 is a diagram showing the mating of a module to the chassis in the computer system of FIGS. 1 and 2, in accordance with one embodiment of the invention;

FIG. 4 is a schematic diagram showing the transmission of power and control signals through the module of FIG. 3;

FIG. 5 is a schematic diagram showing a powered module ejector for use in removing a module from the system of FIG. 1 in accordance with one embodiment of the invention; and

FIG. 6 is a flowchart depicting the operations involved in removing a module from a system in accordance with one embodiment of the invention.

### DETAILED DESCRIPTION

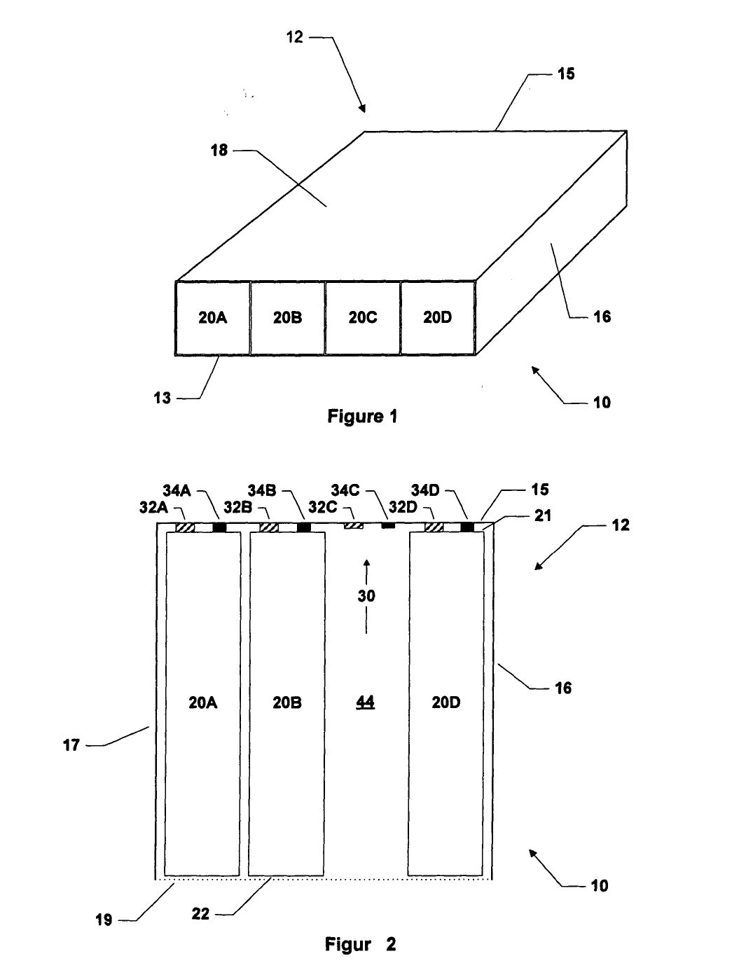

FIGS. 1 and 2 provide a simplified schematic illustration of a typical computer rack system 10. In particular, computer system 10 comprises a shelf or chassis 12 defined by top wall 18, bottom wall 13, side walls 16, 17, and rear wall 15. The shelf 12 accommodates multiple modules 20A, 20B, 20C, and 20D, which are positioned within corresponding slots 44 in the shelf 12. Note that in FIG. 1, the chassis is fully occupied by the four inserted modules 20A, 20B, 20C, and 20D, and there are no vacant slots, while FIG. 2 depicts the situation in which module 20C has been removed, thereby creating one vacant slot 44.

The orientation of shelf 12 is such that the modules are inserted from the front 19 of the shelf 12 towards the rear wall 15 of the shelf. The direction of insertion of a module, represented by arrow 30 in FIG. 2, is therefore towards the rear wall 15, parallel to the two side walls 16, 17 of the shelf. Conversely, the direction of retraction of a module from chassis 12 is in the opposite direction (i.e. the reverse of arrow 30).

The modules within system 10 represent field replaceable units (FRUs), whereby a technician in the field may add a FRU into or remove a FRU from an operational system 10. Such a service action might be undertaken either as a replacement for an existing unit (whether because the existing unit has failed, or because it no longer has sufficient capacity and so needs to be upgraded), or to supplement the existing configuration, such as by adding another module 20 into the system 10 (assuming that there is a suitable vacant slot).

It will be appreciated that there are many potential variations on the configuration shown in FIGS. 1 and 2. For example, system 10 may contain only one shelf 12, as illustrated in FIG. 1, or it may contain multiple shelves stacked one on top of another. In this case, the top wall 18 of one shelf may form the bottom wall 13 of the shelf above. If multiple shelves are present, then typically the shelves are similar to one another, although there may be variations, for example, in the number and type of slots that the shelves are provided with.

The chassis 12 in FIG. 1 contains four equally sized modules, but many systems accommodate a much larger number of modules within one shelf. In addition, some systems may support a heterogeneous selection of modules within a particular shelf. Note if the number of modules within a shelf is significantly increased from that shown in FIG. 1 (e.g. to sixteen), this is normally accomplished by shrinking the module width (i.e. the dimension perpendicular to side walls 16 and 17). This results in a relatively planar shape of a module, conforming to the general dimensions of a typical PCB (the width of the module now corresponding to the thickness of the PCB plus depth of mounted components).

The chassis 12 of FIG. 1 accommodates horizontally arranged modules (i.e. module 20A is horizontally adjacent to module 20B, which is horizontally adjacent to module 20C, and so on). However, it is also possible for modules to be stacked vertically, one on top of another. Typically in this arrangement, the modules comprise PCBs, with the plane of each PCB extending from one side wall 16 to the other 17. For such vertical stacking, the chassis 10 generally represents a relatively tall rack structure, thereby allowing many (horizontal) PCBs to be inserted. The rack structure in such a vertically stacked system may optionally be subdivided by shelves, to allow groups of modules to be partitioned.

For the horizontal layout of FIG. 1, each module 20 is generally supported by at least one of the bottom wall 13 and/or the top wall 18 of the chassis 12. It is also possible for each slot 44 to be provided with side walls running parallel to the chassis side walls 16 and 17, and these can also be used to support the modules. (N.B. the embodiment of FIGS. 1 and 2 does not have side walls for individual slots). Other structures (e.g. rails) may also be provided within chassis 12 in order to support inserted modules 20.

As depicted in FIG. 2, each slot 44 in chassis 12 is provided with a mechanical restraint 34A, 34B, 34C, 34D on the back wall 15. This co-operates with a corresponding restraint on the leading edge 21 of an inserted module 20 to hold the module in place, once the module has been inserted into the chassis 12. Furthermore, each slot also has a connector 32A, 32B, 32C, 32D provided on the rear wall 15 of chassis 12. These connectors likewise mate with corresponding connectors on the inserted modules 20. Note that the connectors 32 on the chassis are linked to various power and signal supply networks provided within chassis 12. These networks allow power and data signals to be provided to the various modules 20 within system 10, as well as permitting both internal and external communications, i.e. to other modules in system 10, and also to external components and networks. (N.B. these power and signal distribution networks are not depicted in FIGS. 1 and 2).

Note that the configuration and layout of electrical connectors 32 and mechanical restraints 34 are shown only schematically in FIG. 2. For example, there may be multiple electrical connectors 32 per module, and/or multiple mechanical restraints 34 per module. Also, rather than being positioned side by side, the electrical connector(s) may be positioned above or below the mechanical restraint(s), or they may have any other appropriate physical layout on rear wall 15. A further possibility is that the electrical connectors and mechanical restraints are integrated together into a single unit.

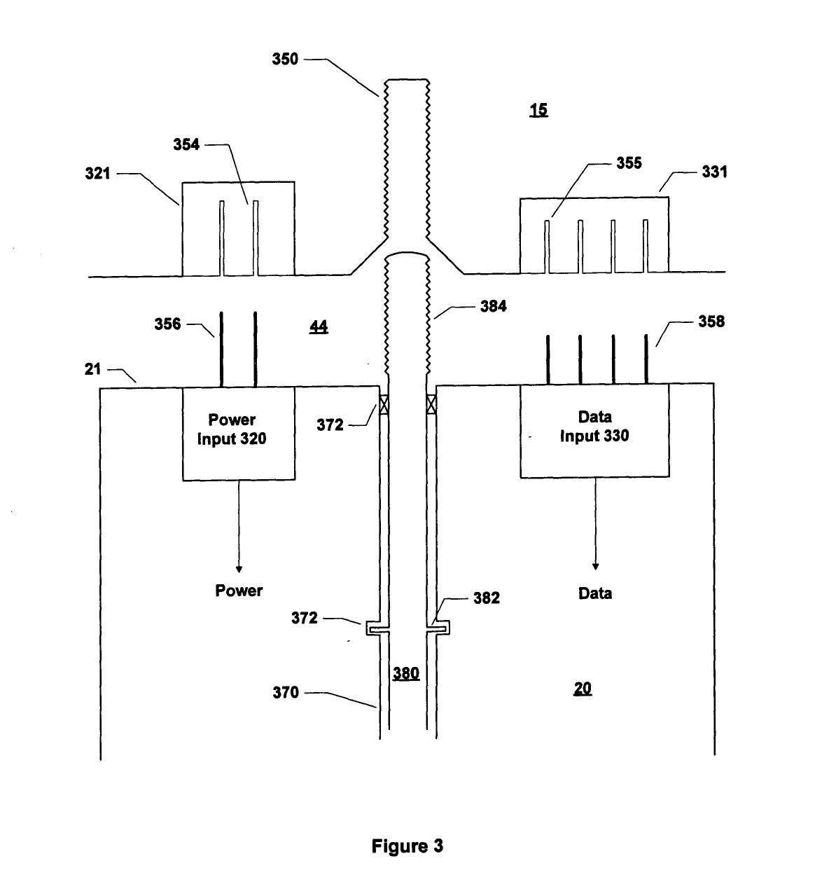

FIG. 3 depicts in more detail the interface between a module 20 and the chassis 12 in accordance with one embodiment of the invention. Module 20 incorporates a hollow shaft 370, which in turn accommodates a bolt 380. Bolt 380 is supported within shaft 370 by bearing 372 (and optionally other bearings, not shown in FIG. 3). This allows bolt 380 to rotate within the shaft 370. Bolt 380 has a radial flange 382 that is accommodated within a sleeve 372 provided in shaft 370. The flange 382 and the corresponding sleeve 372 do not hinder the rotation of the bolt within bearing 372, but they constrain axial movement of the bolt 380 along shaft 370. Thus, there is only a controlled and limited amount of axial play, as defined by the axial length of the sleeve 372.

A portion 384 of bolt 380 extends beyond the leading edge 21 of module 20 (i.e. the edge of module 20 that is first inserted into slot 44). This portion 384 is provided with a screw thread. The rear wall 15 of the chassis has a corresponding screw hole 350. Accordingly, when the screw head 384 of bolt 380 is inserted into hole 350 and rotated, the module 20 is drawn towards the back of the slot, and into full engagement with rear wall 15.

Note that the entrance of screw hole 350 is tapered. This helps to bring the screw head 384 into proper alignment with hole 350, thereby easing the module insertion process, and ensuring that the electrical connectors mate properly with one another (as described in more detail below). An alternative approach for achieving such alignment would be to taper the screw head 384, in which case hole 350 would likewise be provided with a similar taper (as opposed to the generally cylindrical shape illustrated in FIG. 3).

FIG. 3 also illustrates the electrical connections that are made between module 20 and the rear wall 15 of the chassis when the module is inserted into slot 44. Two separate connector pairs are shown, one for providing power to module 20, the other representing a data communication facility. Thus module power connector 320 has protruding pins 356 that mate with corresponding slots 354 in the chassis power connector 321. Likewise, the module data input connector 330 has protruding pins 358 that mate with corresponding slots 355 on the chassis data connector 331.

It will be appreciated that bolt 380 and inlet 350 in combination with one another represent the mechanical restraint 34 illustrated in FIG. 2. In particular, they prevent module 20 from being withdrawn from slot 44 unless bolt 380 is properly rotated. Similarly, power input connectors 320, 321 and data input connectors 330, 331 in combination represent the electrical connector 32 illustrated in FIG. 2.

Note that again the depiction of connectors 320, 321, 330, 331 in FIG. 3 is simplified and schematic. Thus there may be multiple data input connectors, each of which typically includes a large number of pins (sometimes 100 or even 1000). It will also be appreciated that the relative positioning of the different connectors 320, 330, together with locking mechanism 380, on the leading edge 21 of module 20 will vary from one embodiment to another, in accordance with the design characteristics and layout of the module or slot interface in question.

In addition, the connector pins 356 and/or 358 are often recessed within a connector sleeve for protection, as is common in modern connectors, with the counterpart module connectors 321, 331 then being configured accordingly. Likewise, bolt-thread 384 may also be recessed in order to reduce the risk of any physical damage during handling of the module. In this situation, back wall 15 would have a portion that protrudes into the slot 44, and also into module 20 (after insertion), with the bolt-hole 350 then being sunk into this protruding portion to receive the (recessed) bolt from the module. Alternatively, the back wall may be provided with the male member of the connector, protruding into slot 44, while the module would be provided with a corresponding female member, recessed into the body of the module (and rotatable).

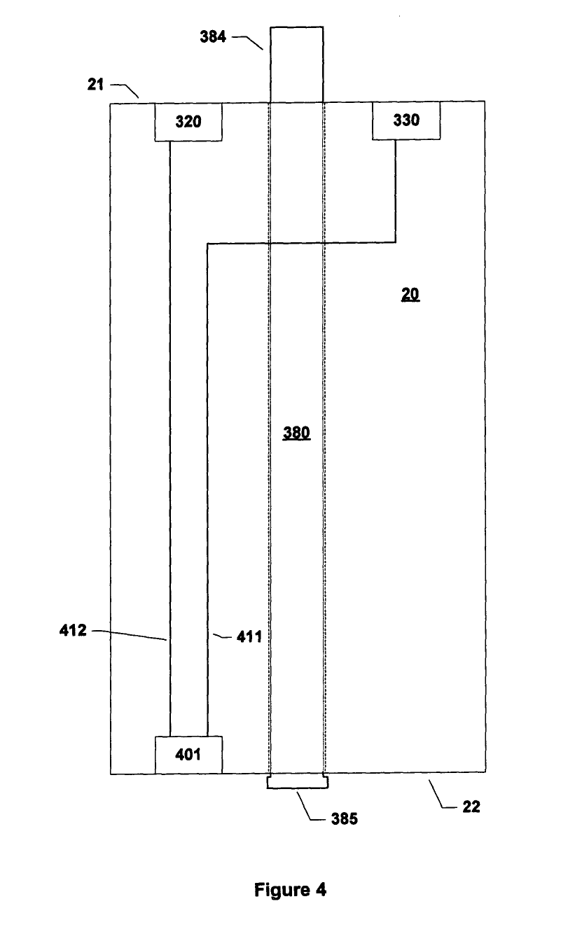

FIG. 4 illustrates module 20 (omitting for reasons of clarity various details, such as the thread and flange on bolt 380 and the pins on connectors 320 and 330). In particular, FIG. 4 depicts module 20 from its the leading edge 21, which engages the rear wall 15 of the chassis, through to its trailing edge 22. It will be appreciated that once module 20 has been inserted into slot 44, only this trailing edge 22 is generally accessible to a visiting service engineer.

As shown in FIG. 4, bolt 380 extends the entire length of module 20. At one end of bolt 380 there is a screw portion 384, which protrudes from module 20 in order to engage with a corresponding screw hole 350 in the chassis (as previously described in relation to FIG. 3). At the other end of bolt 380 is a screw-head 385, which allows bolt 380 to be manipulated (rotated) from the front of the module. Note that although head 385 is shown in FIG. 4 as protruding slightly from the front face 21, head 385 may instead be flush with this face or indeed even recessed, as long as it remains accessible to an engineer.

Also shown in FIG. 4 are electrical lines 412 and 414, both terminating at socket or connector 401 located on the front wall 21 of module 20. Line 412 runs from power connector 320 and so provides a power feed to socket 401. Line 411 (which is discussed in more detail below) runs from data connector 330, and therefore provides a data or control input to socket 401.

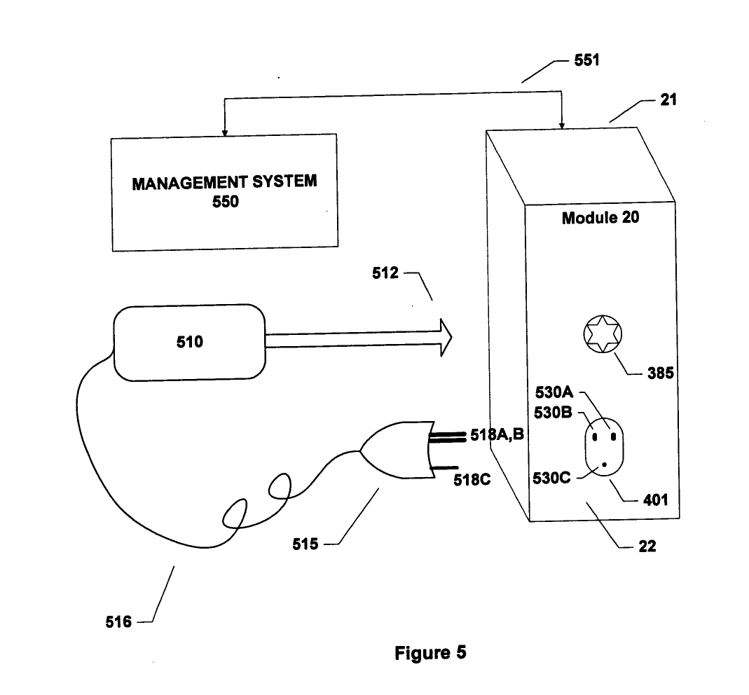

FIG. 5 illustrates the front wall 21 of module 20, including screw-head 385 and socket 401. Note that screw-head 385 has a somewhat unusual shape. This matches a corresponding special purpose head 512 on electric screw-driver 510. The presence of the specialised screw-head 385 on bolt 380 makes it difficult for anyone to remove module 20 from its slot 44 by unscrewing bolt 380 unless they have the proper specialised equipment (i.e. electric screwdriver 510 provided with head 512 to engage screw-head 385). It will be appreciated that while FIG. 5 shows one possible shape for a specialised screw-head (a six-pointed star), any other appropriate shape could be used instead (e.g. a triangle, a T-shape, etc.).

The electric screwdriver 510 has a plug 515 which is inserted into socket 401. More particularly, plug 515 has two pins 518A, 518B that are received into corresponding slots 530A, 530B in socket 401. Slots 530A, 530B are in turn connected to power line 412, and so are able to provide drive power to electric screwdriver 510. The remaining pin 518C on plug 515 engages slot 530C in socket 401. This pin provides a control signal that is received at socket 401 via data line 411 from data connector 330. The origin of this control signal is management system 550, which represents a service processor or some other supervisory system for managing the operations of system 10. Thus management system 550 determines whether or not to allow the removal of module 20 from its respective slot 44, and sends an appropriate control signal to enable or disable this operation over line 551. This is passed via data connector 331 on the chassis through to data connector 330 on the module, and then via line 411 through to socket 401, for eventual receipt by electric screwdriver 510.

Plug 515 is attached to the body of screwdriver 510 by lead 516. Note that in one embodiment, lead 516 has a restricted length. This then prevents the plug 515 of the screwdriver engaging a socket 401 of a first module, while the head 512 of the screwdriver engages the screw-head 385 of a second (different) module. Accordingly, the screwdriver can only be used to remove the particular module from which the appropriate control signal is currently being received (rather than some adjacent module).

Note that in one embodiment, screwdriver 510 is based on a conventional electric (powered) screwdriver that is fitted with a special adapter. This adapter might (for example) be held in the chuck of the screwdriver. Electronics in the adapter then enable battery power to the screwdriver only if the control signal is being received.

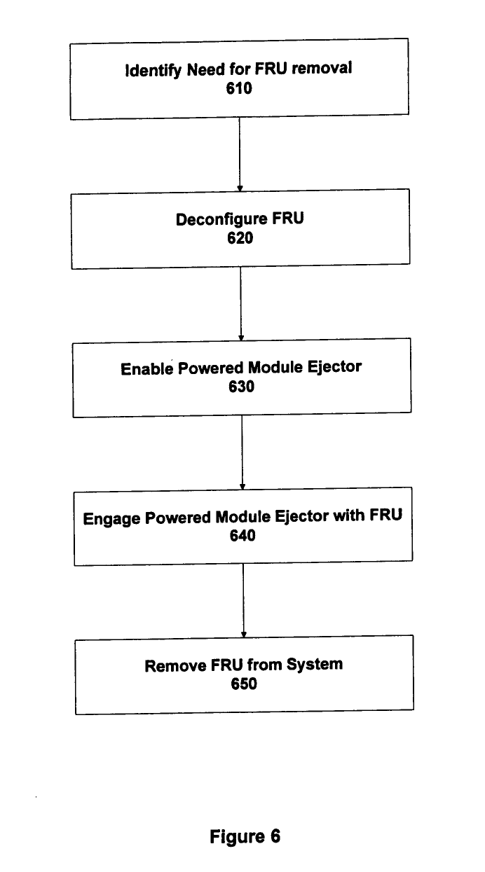

The use of electric screwdriver 510 to remove a module or FRU from system 10 in accordance with the received control signal is illustrated in the flowchart of FIG. 6. The method commences with the identification of the need for the FRU to be removed from its slot (step 610). Depending on the particular circumstances, this action or diagnosis may be performed by a visiting engineer, or perhaps by the management system 550. For example, if the service operation is to replace one module 20 with another one of higher capacity in order to upgrade the system, then normally this operation will be initiated by the engineer. On the other hand, if the module 20 is being replaced because it has developed a fault, then this may possibly have been diagnosed already by the management system 550.

Once the FRU to remove has been identified, and the management system 550 notified accordingly (if it did not previously know the identity of the relevant FRU), the management system 550 proceeds to deconfigure the relevant FRU (step 620). This ensures that the remainder of system 10 does not subsequently try to utilise or communicate with module 20, so that its removal cannot lead to any further disruption of processing that is occurring within system 10.

Once the module has been successfully deconfigured, the management system 550 sends an enable signal over line 551 (step 630). As previously described, the enable signal is therefore transmitted to screwdriver 510 via socket 401 and plug 515. Electric screwdriver 510 is designed such that it will not operate without the presence of the enable signal. Accordingly, it is not possible to use electric screwdriver 510 to remove module 20 unless and until the management control system 550 has provided a suitable enablement signal. Therefore, the module 20 can only be removed after it has been properly deconfigured by the management system. (This also implies that an engineer is prevented from trying to remove the wrong module by mistake, since the management system 550 will not have deconfigured such an incorrect module for removal, hence there will not be a corresponding enable signal for it).

The electric screwdriver 510 is now engaged with the FRU to be removed (step 640), by bringing screwdriver head 512 into contact with bolt head 385, and by inserting the plug 515 into socket 401. At this point, the screwdriver 510 is now powered and enabled, and can therefore turn bolt 380 to remove module 20 from its slot 44 (step 650). (Note that the engineer may engage screwdriver 510 with module 20 somewhat earlier in proceedings, perhaps prior to the module 20 being deconfigured; however, in this case the electric screwdriver would remain inoperable until the enable signal was received via pin 518C).

It will be appreciated that the electric screwdriver 510 is only powered by module 20 for as long as module power pins 356 remain within corresponding slots 354. Thus after the power input connector 320 has been separated from the chassis power connector 321, socket 401 can no longer supply power through to the screwdriver 510.

The timing of this power cut-out depends on the relative length of power connector pins 356 and the protruding portion 384 of bolt 380 (in conjunction with slots 354 and hole 350 respectively). Thus if the protruding bolt portion 384 is shorter than the power connector pins 356, then the bolt 380 will be fully removed from the hole 350 in the rear wall 15 of the chassis before power to the module is disconnected. At this point, module 20 can simply be pulled out of slot 44, since the bolt 380 is now disengaged, and so no longer provides any mechanical restraint to retain module 20 within slot 44. Note that this may potentially render the power input pins 356 vulnerable to damage during module insertion or removal, since when pins 356 initially start to enter slots 354, the alignment and applied force are not yet controlled by the engagement of bolt 380 with corresponding hole 350. On the other hand, power pins can generally be made quite large and rather robust, thereby reducing any such risk.

An alternative possibility is to have the protruding portion 384 of bolt 380 extend past pins 356 (this arrangement is depicted in FIG. 3). Consequently, the power input pins 356 disengage from slots 354 prior to the bolt thread 384 disengaging from hole 350. The benefit of this is that the bolt 380 can now be used to guide and control the insertion of module 20 into slot 44, and more particularly the mating of electrical connector pairs 320, 321, and 330, 331. However, it does imply that the electric screwdriver 510 will stop receiving power from socket 401 before the bolt 380 is fully removed from hole 350. One possibility in such circumstances is for the remaining portion of the bolt head 384 to be removed from hole 350 by manually rotating screwdriver 310 and hence bolt 380.

Another factor to be considered is that the enabling control signal itself from management system 550 may be disconnected prior to disengagement of bolt 380 or disconnection of power connectors 320, 321. This circumstance can be handled in a variety of ways, including by manual rotation of the screwdriver 510 from this point onward. Another possibility is to provide a wireless path such as an infrared link (not shown in FIG. 3) between the module and the chassis for the control signal. This ensures that that the control signal is not lost when data connectors 330 and 331 disengage. Alternatively, the electric screwdriver 510 may be designed so that continued provision of the control signal is not required during the final stages of module removal. For example, the electric screwdriver may continue powered operation for a predetermined period of time after loss of the enable signal. A further option is for the screwdriver to somehow sense or determine the position of the module relative to the chassis, and only to require an enabling control signal when the module is fully inserted into the chassis.

It will be appreciated that any ability to allow the manual withdrawal of bolt 380 does potentially allow enable pin 518C to be circumvented. Thus an engineer might perhaps initially try to withdraw bolt 380 manually using screwdriver 510, an action which is not regulated by the enable signal. However, in practice it is normally much more difficult and cumbersome to operate screwdriver 510 manually to retract a module than to use screwdriver 510 in powered mode. Accordingly, an engineer is always likely to attempt the latter (powered) option first. Any failure at this point, before the module has started to withdraw from slot 44, will then alert the engineer to the fact that the enable signal had not been set. This should prompt the engineer to confirm specifically the correctness the proposed FRU removal (i.e. that the right module was being removed, and that a proper deconfiguration had been performed). Consequently, the most common types of mishap are protected against.

In fact, an ability to override the control signal from the management system can be important in its own right, for example, should the control signal itself somehow become unreliable or corrupted (perhaps because data input connector 331 is malfunctioning). It is therefore desirable to have a fall-back mechanism for removing module 20 from slot 44 should such a failure occur. The manual operation of screwdriver 510 provides such a mechanism, without undermining the general safeguards provided by the use of the control signal (for the reasons just discussed).

It should be appreciated however that since the components within the module mechanism just described are generally passive, the risk of failure of these components is actually very low. Thus bolt 380 is driven by an external screwdriver 510 rather than having any complex internal electrical drive mechanism. In addition, power line 412 and control signal 411 simply transmit power and an enable signal respectively, and do not require any sophisticated electronics to be incorporated into the module itself.

Although FIGS. 1 to 6 have presented certain implementations of system 10 and powered screwdriver 510, it will be appreciated that there are many other possible variations on the embodiments so far described. For example, screwdriver 510 may be a battery-powered device. This would allow the screwdriver 510 to continue operating even after the power input pins 356 had disengaged from slots 354, without requiring any manual stage of operation. The plug 515 would then engage socket 401 simply to receive the enable signal (not power as well). Note that in this arrangement, the screwdriver 510 should be configured so that it does not operate in electric mode (i.e. as an electric screwdriver) unless an enable signal is received via socket 401. In other words, if plug 515 is not inserted into socket 401, then the screwdriver 510 is disabled, since no enable signal is being provided. Consequently, an engineer is not able to remove a configured FRU simply by forgetting to connect plug 515 into socket 401.

Although FIG. 5 depicts the use of a wired connection to provide the enable signal between module 20 and screwdriver 510, any appropriate form of wired or wireless link might be used. For example, the control signal could be provided over an infrared or microwave link from the module to the screwdriver. Note however that any wireless signal has to be localised to the corresponding module. This avoids the screwdriver receiving an enable signal from one module, and then being used to remove a different—incorrect—module. Such localisation might be achieved by having a limited range on the wireless link, and/or by having restricted directionality on the signal.

In one embodiment, a lamp (optical or perhaps near-IR) may be used to provide a wireless connection between the module and the powered module injector. Such a lamp may be located on the module itself, and operated by the module in accordance with the control signal received from the chassis. Alternatively, the lamp may be located on the back wall 15 of the chassis and operated directly by the management system (typically via the chassis backplane). In this case, the module can incorporate a light guide to convey the lamp output from the back wall through the module so as to be externally accessible from the front of the module. This then allows the presence (or absence) of the control signal to be determined by the powered module ejector by detecting whether any light is emanating from the light guide. Note that since a light guide is generally a passive device, it is expected to have a high degree of reliability.

The control signal from the management system to the powered module ejector (however transmitted) may be used not only to enable the powered module ejector, but also potentially to supply other information relevant to the service operation. For example, the powered module ejector may be settable to a particular maximum torque to try to avoid damage by an engineer applying excessive force during a service operation (perhaps in the event of some connector misalignment). In one embodiment, the control signal from the management system therefore includes an indication to the powered module ejector of the maximum torque to be used in respect of the particular module to be removed or inserted (this is likely to vary according to the type of module and chassis). This control signal can then be used to regulate the maximum amount of force that may be applied by the powered module ejector.

The above embodiments have generally used a single insertion bolt 380 to guide module 20 into proper alignment with slot 44 and to restrain the module 20 in engagement with the chassis. However, it will be appreciated that better alignment can generally be achieved by having two or more insertion bolts through module 20 that are parallel to one another, but separated from each other. This would then prevent any rotation of the whole module about a single bolt. Note that the multiple bolts should be driven in synchronism with one another, in order to ensure that the module does not become misaligned on insertion or removal (if one bolt is inserted or retracted ahead of the others). Various suitable drive mechanisms for such synchronous rotation are known to the skilled person, and may involve having one bolt as the master, and others as slaves (in which case screwdriver 510 rotates the master, and the slave bolts follow). Alternatively, a separate drive head may be provided on the module, for example intermediate the two (or more) bolts, and the screwdriver is then used to turn this special drive head, which in turn results in corresponding rotation of the two (or more) bolts.

While bolt 380 provides a convenient restraint for retaining a module in a slot, the skilled person will be aware of various other approaches for providing such a restraint. For example, the module and the chassis may be provided with a rack and pinion mechanism for moving the module into and out of its slot. In this case, the visiting service engineer may have some special purpose device for activating and driving the rack and pinion mechanism, rather than electric screwdriver 510. Thus in more general terms, a service engineer is provided with a portable device for powered ejection of a module (subject of course to receipt of the relevant enable signal from management system 550).

It is also possible for system 10 to be provided with some form of electrical latching arrangement (not shown in the Figures). Such a latch could then open or shut in accordance with the setting of enable signal received over line 551, thereby providing an additional safeguard against inadvertent removal of module 20. Note that such a latching system should again have a manual override, just in case some malfunction developed in the latching system itself.

A wide range of other variations in design are also possible. For example, the slot 44 may be provided with guide rails to aid the insertion of a module into the slot. In addition, the bolt (or other form of restraint) may not extend to the front of the module, as long as it remains accessible from the front of the module (e.g. the blade of screwdriver 510 may be inserted a significant distance down shaft 370 in order to engage the head 385 of the bolt). Likewise, the socket 401 or other interface for providing the control signal from the module to the screwdriver or other module ejection device may be recessed into the module, again provided that the control signal remains accessible from the front of the module.

In addition, while the control signal has been implemented in the above embodiments as a one-way communication from the management system to the powered module ejector (via the module), the same path could be used for two-way communications. For example, the management system might be able to automatically detect the engagement of plug 515 into socket 401 (see FIG. 5). This might be achieved simply by an inserted pin 51 8C completing a circuit, or perhaps an additional pin could be used for this purpose. Two-way communications could also be established with a wireless link, if so provided for the control signal.

One potential use for a bi-directional link is for the powered module ejector to signal to the management system that it is intended to remove the relevant module. In other words, as the powered module ejector is plugged into (or otherwise engages) a module, this results in a request to the management system to be allowed to remove the module. If such request is appropriate, for example, the module is known by the management system to be faulty or is otherwise planned for a service operation (perhaps an upgrade), then the management system can set the control signal to enable the powered module ejector to remove the module. Note that prior to setting the control signal, the management system may delay until any operations involving the module have completed and (or) reconfigure the system so as not to use the module that is about to be removed.

A further concern is that hot removal or insertion of a module on a bus, which is typically a simple passive interconnect where multiple modules share a single set of electrical wiring, can introduce noise on the bus that may potentially corrupt signalling between those modules still in use. To avoid such problems, one option is therefore to stop using the bus while module insertion or removal is taking place. This can be coordinated by the management system, which in response to a notification that a module is about to be removed, prevents use of the bus prior to providing the enabling control signal. Use of the bus can then be restored once the module has been physically removed from the system. This brief interruption in service would typically not be perceptible to a user.

Note that a similar approach can be taken even where the link used for the control signal is not bidirectional. For example, the management system may as a precaution automatically shut down a bus for a limited time period during which the control signal for a module attached to the bus is enabled. This might occur irrespective of whether the module in question has actually been engaged by a powered module ejector.

In conclusion, although the approach described herein is typically intended for use in a computer system, it is applicable to any electronic system that has one or more FRUs or modules mounted in a chassis. It will be appreciated that this includes a wide variety of computing systems (mainframe, server, workstation, desktop, etc.), plus a great range of electronic systems (e.g. telecommunications apparatus, subsystems for transport devices such as aeroplanes, and so on).

Thus while a variety of particular embodiments have been described in detail herein, it will be appreciated that this is by way of exemplification only. The skilled person will be aware of many further potential modifications and adaptations that fall within the scope of the claimed invention and its equivalents.

1. Apparatus comprising:
a chassis having a plurality of slots, each slot being capable of receiving an electrical module having opposed front and back portions, wherein the back portion of a module is inserted first into a slot;
a module inserted into one slot of said plurality of slots and having on its back portion at least one module electrical connector in engagement with a mating chassis electrical connector, and at least one module restraint in engagement with a mating chassis restraint to retain the module in the slot; and
a management system operable to configure and deconfigure modules inserted in the slots, and to generate a control signal for said inserted module indicative of whether the module may be removed from its respective slot, said control signal being received by the inserted module and made externally accessible via an interface on the front portion of the inserted module.

2. The apparatus of claim 1, wherein said control signal is provided from the management system to the module via the chassis electrical connector and the module electrical connector.

3. The apparatus of claim 1, wherein the control signal is set to indicate that a module can be removed from its slot provided that the module has been deconfigured by the management system.

4. The apparatus of claim 1, wherein the control signal is set to indicate a maximum torque to be used in removing a module from its slot.

5. The apparatus of claim 1, wherein said interface comprises a socket for receiving a plug from a handheld module ejector that is operable to disengage the module restraint from the chassis restraint.

6. The apparatus of claim 5, wherein said socket further provides power to the handheld module ejector.

7. The apparatus of claim 1, wherein said control signal is externally accessible via a wireless data link.

8. The apparatus of claim 1, wherein said control signal is provided by a lamp on the chassis, and said inserted module includes a lightguide to render the control signal externally accessible.

9. The apparatus of claim 1, wherein said module restraint extends from the back portion of the module, where it engages the chassis restraint, to the front portion of the module, where it is externally accessible for manipulation by a handheld module ejector.

10. The apparatus of claim 9, wherein said module restraint comprises a bolt with a screw thread, and said chassis restraint comprises a recess with a screw thread for receiving and engaging the bolt.

11. The apparatus of claim 10, wherein said module restraint comprises a plurality of parallel bolts, each bolt having a screw thread, and said chassis restraint comprises a corresponding plurality of holes, each hole having a corresponding screw thread for receiving and engaging a respective bolt, said module including a drive mechanism to rotate the plurality of bolts in synchronism with one another.

12. The apparatus of claim 9, wherein said chassis restraint comprises a bolt with a screw thread, and said module restraint comprises a recess with a screw thread for receiving and engaging the bolt.

13. The apparatus of claim 1, wherein the management system is responsive to an alert signal received from or via the module to deconfigure the module prior to generating said control signal.

14. The apparatus of claim 13, wherein the alert signal is communicated through said interface on the module.

15. The apparatus of claim 1, wherein the chassis includes a bus to which a module is connected after insertion into a slot, and wherein the management system is operable to suspend operations on the bus during insertion or removal of a module to/from the slot.

16. A method of removing an electrical module from apparatus comprising a chassis having a plurality of slots with electrical modules inserted into respective slots and a management system, the method comprising:
determining that a module needs removal from the apparatus;
deconfiguring the module by the management system;
setting a control signal by the management system, said control signal indicating that the module is now ready for removal; and
providing the control signal for external access from the module to be removed.

17. The method of claim 16, further comprising:
receiving the control signal via said external access in a handheld module ejector;
determining in the handheld module ejector whether said control signal is set, wherein said module ejector is inoperative if the control signal is not set.

18. The method of claim 16, further comprising:
receiving an alert signal at the management system from or via the module; and
deconfiguring the module in response to said alert signal prior to setting said control signal.

19. The method of claim 16, wherein the chassis includes a bus to which a module is connected after insertion, and the method further comprises suspending operations on the bus during insertion or removal of a module.

20. Apparatus comprising:
means for receiving a plurality of electrical modules into respective slots in a chassis, wherein a module has opposed front and back portions, such that the back portion is inserted first into the respective slot for the module;
means for providing an electrical connection between a module and the chassis;
means for restraining the module within the chassis;
means for configuring and deconfiguring modules inserted in the slots;
means for generating a control signal for each inserted module indicative of whether the module may be removed from its respective slot;
and means for making the control signal externally accessible via an interface on the front portion of the module when the module is inserted in its respective slot.

21. Apparatus comprising:
a chassis having a plurality of slots for receiving corresponding electrical modules, wherein a module has opposed front and back portions, such that the back portion is inserted first into the respective slot for the module;
a slot having at least one chassis electrical connector for mating with a corresponding module electrical connection on the back portion of an inserted module, and at least one chassis restraint for engagement with a corresponding module restraint on the back portion of an inserted module to retain the module in the slot; and
a communications path for forwarding a control signal from a management system to an inserted module, said control signal indicating for an inserted module whether the module may be removed from its respective slot.

22. The apparatus of claim 21, wherein the communications path includes the chassis electrical connector.

23. The apparatus of claim 21, wherein said chassis restraint comprises a hole with a screw thread for receiving and engaging a module restraint comprising a bolt.

24. The apparatus of claim 21, wherein said chassis restraint comprises a bolt with a screw thread for engaging a module restraint comprising a recessed portion with a screw thread.

25. The apparatus of claim 21, wherein said chassis includes a lamp for providing said control signal.

26. An electrical module for insertion into a rack-mounted system having a plurality of slots, said module having opposed front and back portions, such that the back portion is inserted first into a slot for the module, the module further comprising:
at least one module electrical connector on the back portion of the module for engagement with a mating chassis electrical connector, and at least one module restraint on the back portion of the module for engagement with a mating chassis restraint to retain the module in the slot; and
a communications link extending from the back portion of the module to the front portion, said communications link being operable to receive a control signal from the chassis when the module is inserted in a slot, and to forward the control signal to an externally accessible interface on the front portion of the module, wherein said control signal is indicative of whether the module can be removed from the slot.

27. The module of claim 26, wherein said interface comprises a socket for receiving a plug from a handheld module ejector that is operable to disengage the module restraint from the chassis restraint.

28. The module of claim 27, wherein said socket further provides power to the handheld module ejector.

29. The module of claim 26, wherein said control signal is externally accessible from the module via a wireless data link.

30. The module of claim 26, wherein said control signal is provided by a lamp on the chassis, and said communications link comprises a lightguide extending from the lamp to the externally accessible interface.

31. The module of claim 26, wherein said module restraint extends from the back portion of the module, where it engages the chassis restraint, to the front portion of the module, where it is externally accessible for manipulation by a handheld module ejector.

32. The module of claim 31, wherein said module restraint comprises a bolt with a screw thread.

33. The module of claim 32, wherein said bolt acts as a male connector.

34. The module of claim 32, wherein said bolt acts as a female connector.

35. The module of claim 32, wherein said module restraint comprises a plurality of parallel bolts, each having a screw thread for engagement in a respective one of a corresponding plurality of chassis holes, said module further including a drive mechanism to rotate the plurality of bolts in synchronism with one another.

36. A powered module ejector for use with apparatus comprising a chassis having a plurality of slots, wherein a plurality of electrical modules are inserted into respective slots, a module having opposed back and front portions, such that the back portion is inserted first into the respective slot for the module, and a module having on its back portion at least one module electrical connector in engagement with a mating chassis electrical connector, and at least one module restraint in engagement with a mating chassis restraint to retain the module in the slot;
wherein said powered module ejector receives a control signal from a module, said control signal being indicative of whether the module may be removed from its respective slot, and wherein the powered module ejector is configured to operate only in response to the control signal indicating that the module may be removed from its respective slot.

37. The powered module ejector of claim 36, further comprising a plug for insertion into a socket on a module, wherein said control signal is received from the module via said plug and socket.

38. The powered module ejector of claim 37, wherein said powered module ejector receives power via said plug and socket.

39. The powered module ejector of claim 36, wherein said control signal is received from a module via a wireless data link.

40. The powered module ejector of claim 36, further including a light-sensitive device for detecting a light control signal from the module.

41. The powered module ejector of claim 36, wherein the powered module ejector is configured to be able to engage and to release the module restraint.

42. The powered module ejector of claim 41, wherein said module restraint comprises a bolt with a screw thread, and the powered module ejector comprises an electric screwdriver for rotating said bolt.

43. The powered module ejector of claim 36, wherein if the powered module ejector receives a control signal from a module, there is a physical restriction to prevent the powered module ejector from removing a different module from another slot in the chassis.

44. The powered module ejector of claim 43, wherein said control signal is received via a lead to said module, and said physical restriction comprises a limited length for said lead that prevents the powered module ejector from removing a different module from another slot in the chassis.

45. The powered module ejector of claim 43, wherein the control signal is received from a module via a wireless data link, and said physical restriction comprises a limitation on the range and/or direction of the wireless data link that prevents the powered module ejector from removing a different module from another slot in the chassis.

46. The powered module ejector of claim 36, wherein the powered module ejector is operable to send an alert signal to a management system via a module to be removed to request deconfiguration of the module.

47. The powered module ejector of claim 36, wherein the powered module ejector has a maximum torque setting, which is set in accordance with a value contained in the control signal received from the module.

48. An adapter for operation in conjunction with an electric screwdriver to form a powered module ejector for use with apparatus comprising a chassis having a plurality of slots, wherein a plurality of electrical modules are inserted into respective slots, a module having opposed back and front portions, such that the back portion is inserted first into the respective slot for the module, and a module having on its back portion at least one module electrical connector in engagement with a mating chassis electrical connector, and at least one module restraint in engagement with a mating chassis restraint to retain the module in the slot;
wherein said adapter is operable to receive a control signal from a module, said control signal being indicative of whether the module may be removed from its respective slot, and to permit a supply of power to the electric screwdriver only in response to the control signal indicating that the module may be removed from its respective slot.
